(19) United States
(12) Patent Application Publication
(10) Pub. No.: US 2011/0168234 A1
(43) Pub. Date: Jul. 14, 2011

(54) PHOTOVOLTAIC DEVICE FOR A CLOSELY PACKED ARRAY

(76) Inventors: John Beavis Lasich, Victoria (AU); Pierre Jacques Verlinden, McLaren Vale (AU)

(21) Appl. No.: 12/997,564

(22) PCT Filed: Jun. 11, 2009
(86) PCT No.: PCT/AU2009/000735

§ 371 Date: Mar. 23, 2011

Related U.S. Application Data
(60) Provisional application No. 61/060,734, filed on Jun. 11, 2008.

(51) Int. Cl. H01L 31/05; H01L 31/052

(52) U.S. Cl. 136/246

(57) ABSTRACT

A photovoltaic device comprising a substantially planar photon source facing side, a plurality of edges extending around the perimeter defined by the photon source facing side, and an edge insulator arranged to prevent at least one edge of the plurality of edges from coming into electrical contact with a neighbouring electrically conductive element when the photovoltaic device is arranged as part of an array of photovoltaic devices.

### RELATED APPLICATION

This application claims priority to and benefit from U.S. application 61/060,734 filed 11 Jun. 2008 entitled “A PHOTOVOLTAIC DEVICE FOR A CLOSELY PACKED ARRAY”, the disclosure of which is incorporated herein by reference.

### FIELD

The invention relates to a photovoltaic device for a closely packed array of photovoltaic devices as well as to a photovoltaic module incorporating a plurality of photovoltaic devices, and a receiver comprising a plurality of photovoltaic modules.

### BACKGROUND TO THE INVENTION

In power systems where photovoltaic devices such as where photovoltaic devices in the form of solar cells provide a receiver in a system having a parabolic mirror concentrator or a heliostat field as a concentrator, the photovoltaic devices need to be closely packed in a dense array to make such systems effective and/or more efficient.

Accordingly, there is a need for techniques which allow photovoltaic devices to be closely packed.

### SUMMARY OF THE INVENTION

In a first aspect, the invention provides a photovoltaic device comprising a substantially planar photon source facing side, a plurality of edges extending around the perimeter defined by the photon source facing side, and an edge insulator arranged to prevent at least one edge of the plurality of edges from coming into electrical contact with a neighbouring electrically conductive element when the photovoltaic device is arranged as part of an array of photovoltaic devices.

In an embodiment, the edge insulator insulates at least the most outwardly extending portion of an outer conductive region of the edge.

In an embodiment, the photovoltaic device comprises a plurality of edge insulators insulating respective ones of a plurality of edges.

In an embodiment, the photovoltaic device is rectangular and comprises two to four edge insulators.

In an embodiment, an edge insulator is provided for each edge.

In an embodiment, the photovoltaic device comprises a first contact of a first polarity on the photon source facing side and a conductive interconnect connected between the first contact and a metal layer on a reverse side of the photovoltaic device, the metal layer electrically insulated from a second contact of a second polarity, the interconnect extending around an edge of the photovoltaic device which comprises an edge insulator.

In an embodiment, the photovoltaic device is a photovoltaic cell.

In an embodiment, the photovoltaic cell is a multi-junction cell.

In an embodiment, the multi-junction cell is a triple-junction cell.

In an embodiment, the photovoltaic device is a monolithically integrated photovoltaic module.

In an embodiment, the metal layer is a second metal layer and the second contact is formed by a first metal layer connected to a substrate layer of the multi-junction cell.

In an embodiment, the first and second metal layer are separated by an electrically insulating layer having a heat transfer characteristic sufficient to enable the photovoltaic device to be deployed in a receiver of a solar concentrator power generation system.

In an embodiment, the electrically insulating layer is formed from a material selected from the group including silicon dioxide, silicon nitride, silicon oxy-nitride, aluminium oxide or polyimide.

In an embodiment, each edge insulator is formed from a material which is not wettable by solder.

In a second aspect, the invention provides a photovoltaic module comprising a plurality of photovoltaic devices, each photovoltaic device comprising a substantially planar photon source facing side, and a plurality of edges extending around the perimeter defined by the photon source facing side, the photovoltaic devices closely packed with neighbouring photovoltaic devices such that there are of pairs of neighbouring edges of neighbouring photovoltaic devices which are at risk of coming into electrical contact with one another, and the photovoltaic devices collectively provided with edge insulators such that there is at least one edge insulator for each pair of edges.

In an embodiment, the photovoltaic device comprises an outer periphery and wherein each edge on the outer periphery comprises an edge insulator.

In an embodiment, at least one photovoltaic device has no edge insulators.

In an embodiment, the photovoltaic devices are arranged in a linear array.

In an embodiment, the photovoltaic devices are arranged in a rectangular array.

In an embodiment, at least two edges of each photovoltaic device have insulators.

In an embodiment, each edge of each photovoltaic device has an insulator.

In an embodiment, each edge insulator is formed from a material which is not wettable by solder.

In an embodiment, each photovoltaic device comprises a first contact of a first polarity on the photon source facing side and a conductive interconnect connected between the first contact and a metal layer on a reverse side of the photovoltaic device, the metal layer electrically insulated from a second contact of a second polarity, the interconnect extending around an edge of the photovoltaic device which comprises an edge insulator.

In a third aspect, the invention provides a receiver comprising a plurality of the photovoltaic modules of the second aspect.

In a fourth aspect, the invention provides a photovoltaic device comprising:
a first contact of a first polarity on a photon source facing side;
a second contact on a reverse side of the photovoltaic device, the second contact of a second polarity formed by a first metal layer;
a second metal layer on the reverse side;
at least one separator layer arranged to electrically insulate the first and second metal layers from one another while allowing heat to be conducted from the first metal layer to the second metal layer; and
an electrical interconnect extending from the first contact to the second metal layer.

In an embodiment, the electrical interconnect extends around an edge of the photovoltaic device which comprises an edge insulator.

In an embodiment, the separator layer has a heat transfer characteristic sufficient to enable the photovoltaic device to be deployed in a receiver of a solar concentrator power generation system.

In an embodiment, the electrically insulating layer is formed from a material selected from the group including silicon dioxide, silicon nitride, silicon oxy-nitride, aluminium oxide or polyimide.

In an embodiment, the electrical interconnect comprises an insulating coating facing at least the edge.

In an embodiment, the photovoltaic device is a photovoltaic cell.

In an embodiment, the photovoltaic cell is a multi-junction cell.

In an embodiment, the multi-junction cell is a triple-junction cell.

In an embodiment, the photovoltaic device is a monolithically integrated photovoltaic module.

In an embodiment, the metal layer is a second metal layer and the second contact is formed by a first metal layer connected to a substrate layer of the multi-junction cell.

In a fifth aspect, the invention provides a photovoltaic module comprising a plurality of photovoltaic devices of the fourth aspect connected in an electrical circuit.

In an embodiment, the photovoltaic further comprises a substrate on which the photovoltaic devices are mounted, the substrate thermally connected to a cooling circuit.

In a sixth aspect, the invention provides a receiver comprising a plurality of photovoltaic modules of the fifth aspect.

In a seventh aspect, the invention provides a method of producing electricity comprising concentrating sunlight onto a receiver of the third or sixth aspects.

### BRIEF DESCRIPTION OF THE DRAWINGS

Embodiments of the invention are described further by way of example with reference to the accompanying drawings, in which:

FIG. 1 is a perspective view of an exemplary system for generating electrical power from solar radiation;

FIG. 2 is a front view of the receiver of the system shown in FIG. 1 which illustrates the exposed surface area of the photovoltaic cells of the receiver;

FIG. 3 is a partially cut-away perspective view of the receiver with components removed to illustrate more clearly the coolant circuit that forms part of the receiver;

FIG. 4 is an enlarged view of the section of FIG. 3 that is described by a rectangle;

FIG. 5 is an exploded perspective view of a photovoltaic cell module that forms part of the receiver;

FIG. 6A is a schematic side cross-section of a first arrangement of two neighbouring cell edges;

FIG. 6B is a schematic side cross-section of a second arrangement of two neighbouring cell edges;

FIG. 7 shows a cell edge with an electrical interconnect; and

FIG. 8 is a schematic plan cross-section of a cell;

FIGS. 9A to 9C are schematic plan views of cell having edge insulators having plural insulator members; and

FIGS. 10A and 10B show edge insulators employed in cells which employ wrap through interconnects.

### DETAILED DESCRIPTION

The embodiments provide a photovoltaic device for a closely packed array of photovoltaic devices as well as a photovoltaic module incorporating a plurality of photovoltaic devices, and a receiver comprising a plurality of photovoltaic modules. In one embodiment, the photovoltaic device has an edge insulator in the form of edge insulation on an edge which is at risk of coming into electrical contact with a neighbouring conductive element. In another embodiment, an electrical interconnect is provided in a manner which allows close packing and allows heat to be conducted away from the photovoltaic device. The embodiments may be combined.

The embodiments are of particular use in solar power generation systems which employ a concentrator and a receiver. For example, systems which employ a parabolic mirror concentrator or a heliostat field as a concentrator. However, the embodiment can be employed in other closely packed arrays, for example, in a one-dimensional array in a trough reflector. Other applications include in an array for use in a hybrid photovoltaic/thermal receiver or a photovoltaic receiver where the array of photovoltaic cells receives radiation from a source other than or in addition to direct sunlight, such as infrared radiation radiated from a heated body or light from a source other than the sun. Specific embodiments relate to multi-junction solar cells but aspects of the invention, in particular, the use of an edge insulator can be used with other cell types, for example quantum well type solar cells.

### Exemplary Power Generation System

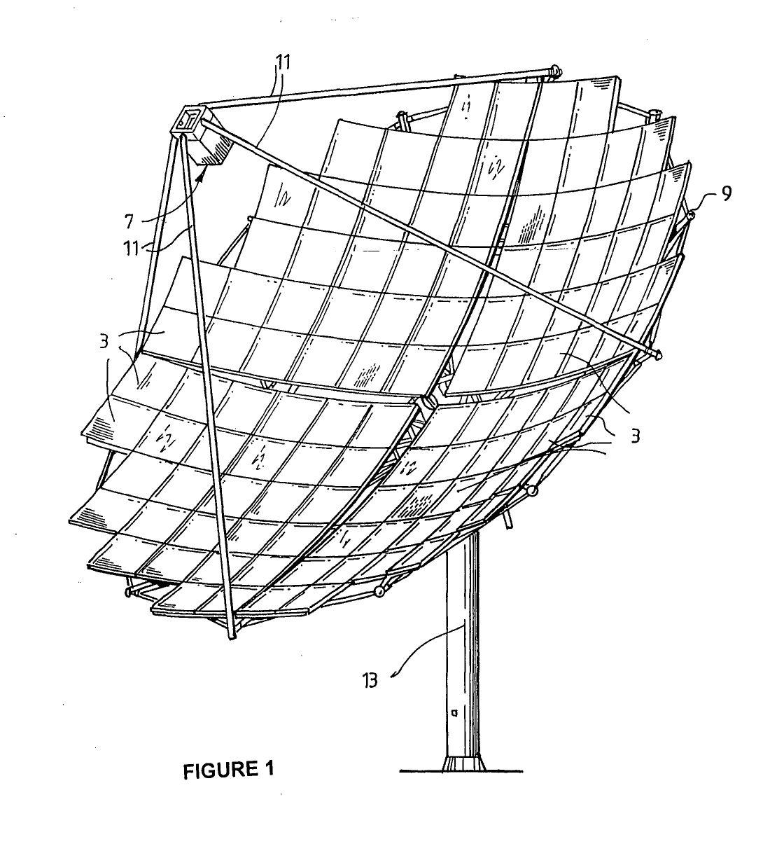

An exemplary solar radiation-based electric power generating system shown in FIG. 1 includes a concentrator 3 in the form of a parabolic array of mirrors that reflects solar radiation that is incident on the mirrors towards a plurality of photovoltaic cells 5.

The cells 5 form part of a solar radiation receiver 7 that includes an integrated coolant circuit. The surface area of the concentrator 3 that is exposed to solar radiation is substantially greater than the surface area of the photovoltaic cells 5 that is exposed to reflected solar radiation. The photovoltaic cells 5 convert reflected solar radiation into DC electrical energy. The receiver 7 includes an electrical circuit (not shown) for the electrical energy output of the photovoltaic cells.

The concentrator 3 is mounted to a framework 9. A series of arms 11 extend from the framework 9 to the receiver 7 and locate the receiver as shown in FIG. 1. The system further includes: (a) a support assembly 13 that supports the concentrator and the receiver in relation to a ground surface and for movement to track the Sun; and (b) a tracking system (not shown) that moves the concentrator 3 and the receiver 7 as required to track the Sun.

As described in further detail in WO 02/080286 which is owned by the present applicant, Solar Systems Pty Ltd, the amount of heat generated by the concentrated light can lead to problems with the operating temperature and performance of the cells 5. To this end, the receiver 7 includes a coolant circuit such as described in WO 02/080286 which can be applied to a wide range of solar cells, including multi-junction solar cells.

The coolant circuit cools the photovoltaic cells 5 of the receiver 7 with a coolant, preferably water, in order to minimise the operating temperature and to maximise the performance (including operating life) of the photovoltaic cells 5.

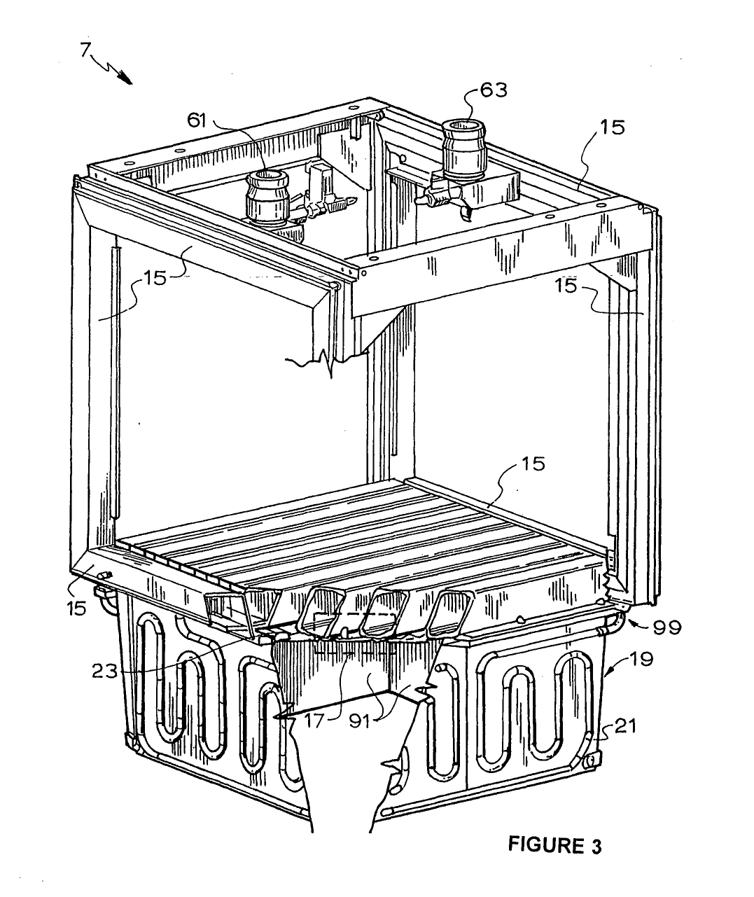

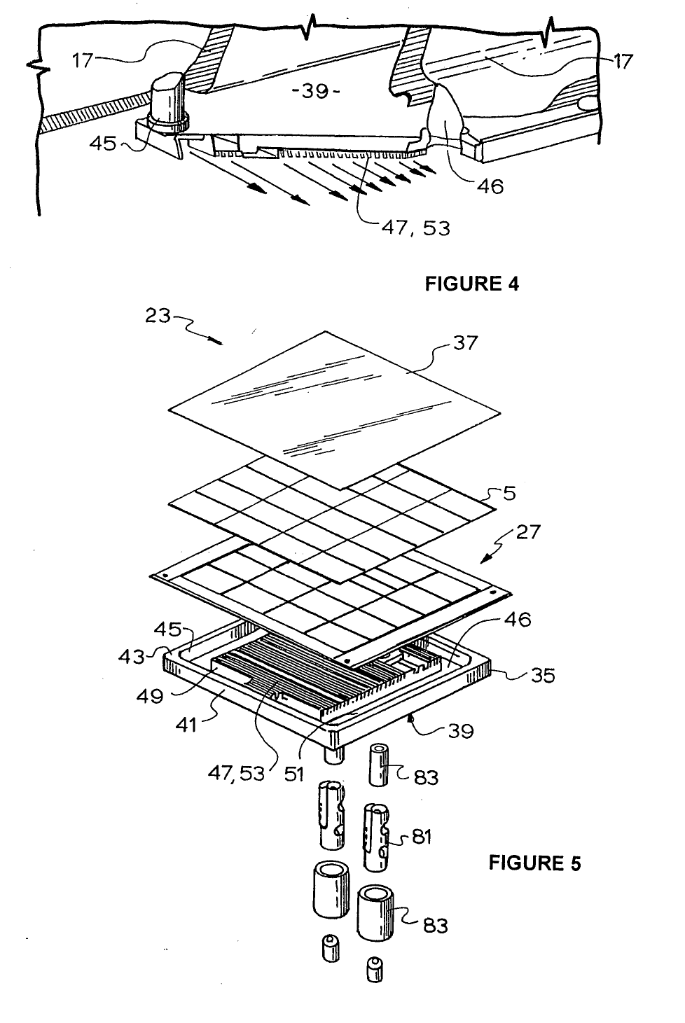

FIGS. 3 and 4 illustrate components of the receiver that are relevant to an exemplary coolant circuit. Other cooling arrangements may also be employed. A number of other components of the receiver 7, such as components that make up the electrical circuit of the receiver 7, are not included in the FIGS. 1 to 5 for clarity.

With reference to FIGS. 3 and 4, the receiver 7 has a generally box-like structure that is defined by an assembly of hollow posts 15. The receiver 7 also includes a solar flux modifier, generally identified by the numeral 19, which extends from a lower wall 99 (as viewed in FIG. 3) of the box-like structure. The solar flux modifier 19 includes four panels 21 that extend from the lower wall 99 and converge toward each other. The solar flux modifier 19 also includes mirrors 91 mounted to the inwardly facing sides of the panels 21.

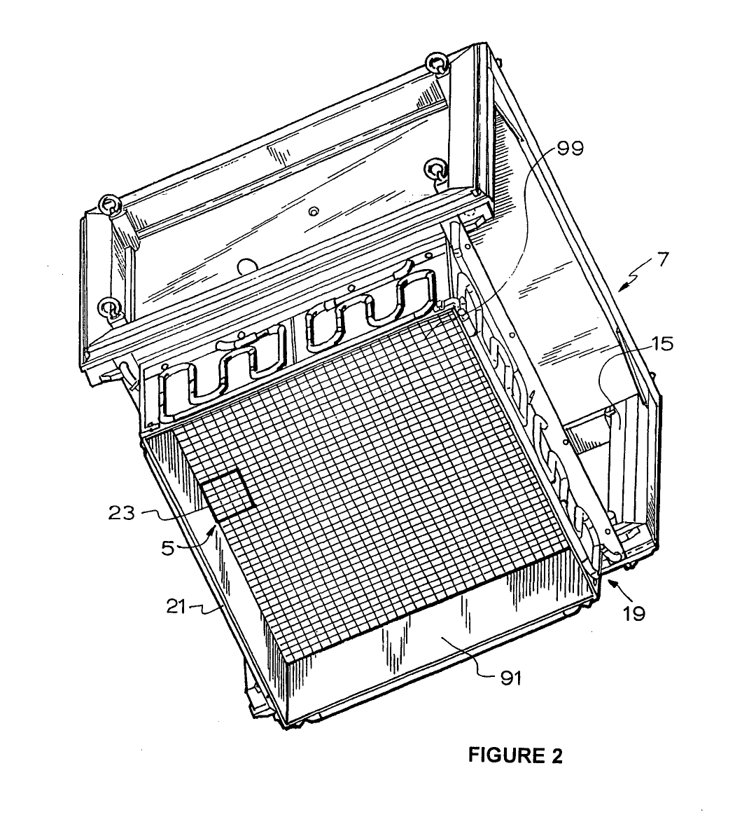

The receiver 7 also includes a dense array of 1536 closely packed rectangular photovoltaic cells 5 which are mounted to 64 square modules 23. The array of cells 5 can best be seen in FIG. 2. In the example, each module includes 24 photovoltaic cells 5 arranged in a 6 cell by 4 cell array. The photovoltaic cells 5 are mounted on each module 23 so that the exposed surface of the cell array is a continuous surface. The modules 23 are mounted to the lower wall 99 of the box-like structure of the receiver 7 so that, in this example, the exposed surface of the combined array of photovoltaic cells 5 is in a single plane.

The modules 23 are mounted to the lower wall 99 so that lateral movement between the modules 23 and the reminder of the receiver 7 is possible. The permitted lateral movement assists in accommodating different thermal expansion of components of the receiver 7.

Each module 23 includes a coolant flow path. The coolant flow path is an integrated part of each module 23. The coolant flow path allows coolant to be in thermal contact with the photovoltaic cells 5 and extract heat from the cells 5 so that the cells 5 are maintained at a temperature of no more than 80° C., preferably no more than 60° C., more preferably no more than 40° C.

The coolant flow path of the modules 23 forms part of the coolant circuit. The coolant circuit also includes the above described hollow posts 15. In addition, the coolant circuit includes a series of parallel coolant channels 17 that form part of the lower wall 99 of the box-like structure. The ends of the channels 17 are connected to the opposed pair of lower horizontal posts 15 respectively shown in FIG. 3. The lower posts 15 define an upstream header that distributes coolant to the channels 17 and a downstream header that collects coolant from the channels 17. The modules 23 are mounted to the lower surface of the channels 17 and are in fluid communication with the channels so that coolant flows via the channels 17 into and through the coolant flow paths of the modules 23 and back into the channels 17 and thereby cools the photovoltaic cells 5.

The coolant circuit also includes a coolant inlet 61 and a coolant outlet 63. The inlet 61 and the outlet 63 are located in an upper wall of the box-like structure. The inlet 61 is connected to the adjacent upper horizontal post 15 and the outlet 63 is connected to the adjacent upper horizontal post 15 as shown in FIG. 3.

In use, coolant that is supplied from a source (not shown) flows via the inlet 61 into the upper horizontal post 15 connected to the inlet 61 and then down the vertical posts 15 connected to the upper horizontal post 15. The coolant then flows into the upstream lower header 15 and, as is described above, along the channels 17 and the coolant flow paths of the modules 23 and into the downstream lower header 15. The coolant then flows upwardly through the vertical posts 15 that are connected to the downstream lower header 15 and into the upper horizontal post 15. The coolant is then discharged from the receiver 7 via the outlet 63. The above-described coolant flow is illustrated by the arrows in FIGS. 3 and 4.

FIG. 5 illustrates the basic construction of each module 23. As is indicated above, each module 23 includes an array of twenty four closely packed photovoltaic cells 5.

Each module 23 includes a substrate 27, on which the cells 5 are mounted. Each module 23 also includes a glass cover 37 that is mounted on the exposed surface of the array of photovoltaic cells 5. The glass cover 37 may be formed to optimise transmission of useful wavelengths of solar radiation and minimise transmission of un-wanted wavelengths of solar radiation.

Each module 23 also includes a coolant member 35 that is mounted to the surface of the substrate 27 that is opposite to the array of photovoltaic cells 5.

The size of the coolant member 35 and the material from which it is made are selected so that the coolant member 35 acts as a heat sink. An exemplary material for the coolant member is copper.

Furthermore, the coolant member 35 is formed to define a set of flow paths for coolant for cooling the photovoltaic cells 5.

Each module 23 also includes electrical connections 81 that form part of the electrical circuit of the receiver 7 and electrically connect the photovoltaic cells 5 into the electrical circuit. The electrical connections 81 extend from a metallised layer of substrate 27 through the coolant member 35. The electrical connections 81 are housed within sleeves 83 that electrically isolate the electrical connections.

The coolant member 35 includes a base 39 and a side wall 41 that extends from the base 39. The upper edge 43 of the side wall 41 is physically bonded to the substrate 27. It can be appreciated from FIG. 5 that the base 35 and the substrate 27 define an enclosed chamber. The base 39 includes a coolant inlet 45 and a coolant outlet 46 located in diagonally opposed corner regions of the base 39.

The coolant member 35 further includes a series of parallel lands 47 which extend upwardly from the base 39 and occupy a substantial part of the chamber.

The upper surfaces of the lands 47 are physically bonded to the substrate 27. The lands 47 do not extend to the ends of the chamber and these opposed end regions of the chamber define a coolant inlet manifold 49 and a coolant outlet manifold 51. The lands 47 extend side by side substantially across the width of the chamber. The gaps between adjacent lands 47 define coolant flow channels 53.

It is evident from the above that the coolant inlet 45, the coolant manifold 49, the flow channels 53, the coolant outlet manifold 49, and the coolant outlet 46 define the coolant flow path of each module 23.

FIG. 4 illustrates the position of one module 23 on the lower wall of the receiver 7. The coolant inlet 45 opens into one coolant channel 17 of the coolant circuit and the diagonally opposed coolant outlet 46 opens into an adjacent coolant channel 17 of the coolant circuit.

In use, as indicated by the arrows in FIG. 4, coolant flows from one supply channel 17 into the inlet manifold 49 via the coolant inlet 45 and then flows from the coolant manifold 49 into and along the length of the channels 53 to the outlet manifold 51. Thereafter, coolant flows from the chamber via the coolant outlet 46 into the adjacent channel 17.

Further details of a receiver are found in WO 02/080286 the disclosure of which is incorporated herein. A further module with alternative coolant flow channels defined by sintered rods is described in WO 2005/022652 and can be adapted for use with this embodiment.

### Embodiment Employing Edge Insulation

Edge insulation can be employed in relation to a wide range of photovoltaic devices including multi-junction cells, silicon cells and monolithically integrated photovoltaic devices, including top-bottom and back connect varieties.

This embodiment is described in relation to a photovoltaic cell in the form of a triple-junction cell, which is part of a general class of cells known as multi-junction cells which employ different materials with different band gaps to absorb energy of photons of differing energy. For example, the highest band gap material is arranged nearest the surface of the cell to absorb high-energy photons while allowing lower-energy photons to be absorbed by the lower band gap material(s) below. This technique can result in much higher efficiencies. However, a particular challenge in a receiver is to pack such cells sufficiently densely without causing undesirable results. This is made more challenging by multi-junction cells because they develop higher voltages such that there is an increased risk of electrical conduction between neighbouring cells when they are closely packed. For example, neighbouring cells in an array of 24 cells series-connected in a triple-junction cell based photovoltaic module have a potential difference of 77V. The voltage increases with the number of cells in series. A similar problem occurs between neighbouring photovoltaic modules (which have even higher potential differences from one another). Monolithically Integrated Modules (MIMs) have been demonstrated with a voltage of 120V. If these MIMS are connected in series in a photovoltaic module, the obtained voltage could be several hundred volts.

To make the photovoltaic modules, photovoltaic devices are typically placed on a substrate by a robotic arm which has a precision tolerance. The smaller the gap between neighbouring devices, the greater the risk that the robotic arm will misplace a device so that it will be in contact with a neighbouring device (or other conductive element) and/or close enough for an electrical discharge (such as a short circuit) to occur, for example if the cell is skewed when placed on the substrate. After the photovoltaic devices are placed on the substrate, they are coated with a non-conductive material, such as silicone, which is also intended to permeate the gaps between photovoltaic devices and photovoltaic modules. As the gap gets smaller, there is also an increased likelihood that the non-conductive material will not adequately fill the gap. For example, as the gap becomes narrower, surface tension may prevent the non-conductive material from flowing into the gap. In the embodiment, the gap between neighbouring cells of the array is approximately 50 microns.

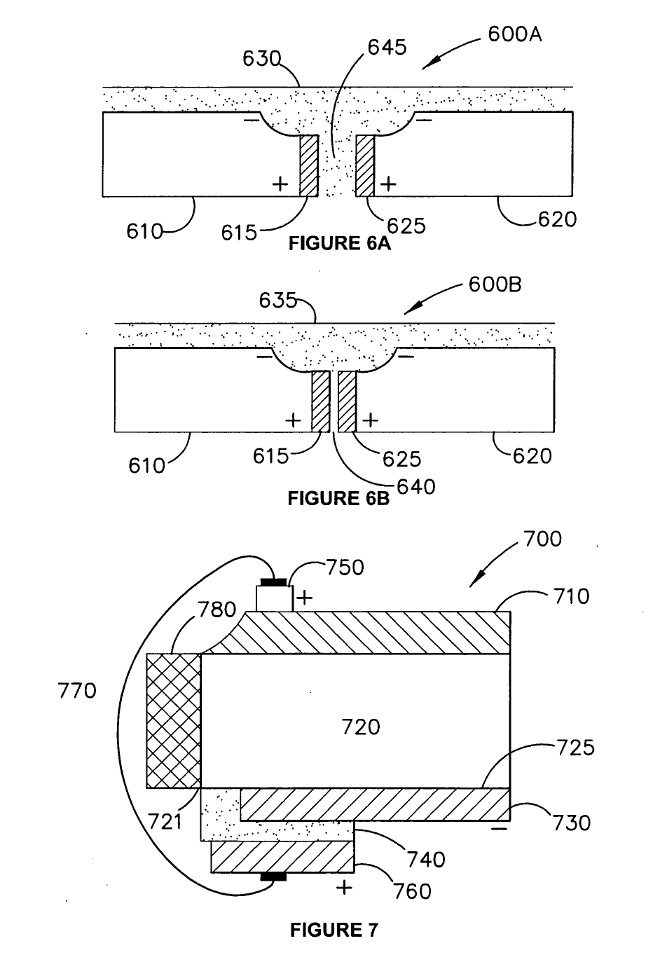

Referring to FIG. 6A there is shown schematically, a first arrangement 600A of a pair of neighbouring cells 610,620 in array 5 which have been placed at the desired separation of 50 microns. The first cell 610 has a first edge insulator 615 and the second cell 620 has a second edge insulator 625. The cells are covered in silicone 630. As the desired separation has been maintained when cells 610,620 were placed on the substrate, silicone 630 has penetrated into gap 645.

In FIG. 6B there is shown a second arrangement 600B of the pair of neighbouring cells 610,620 have been placed too close to one another such that the gap between the cells 610,620 is too small to enable silicone 635 to penetrate. In this arrangement 600B edge insulators 615,625 prevent a short circuit occurring between the neighbouring cells 610,620.

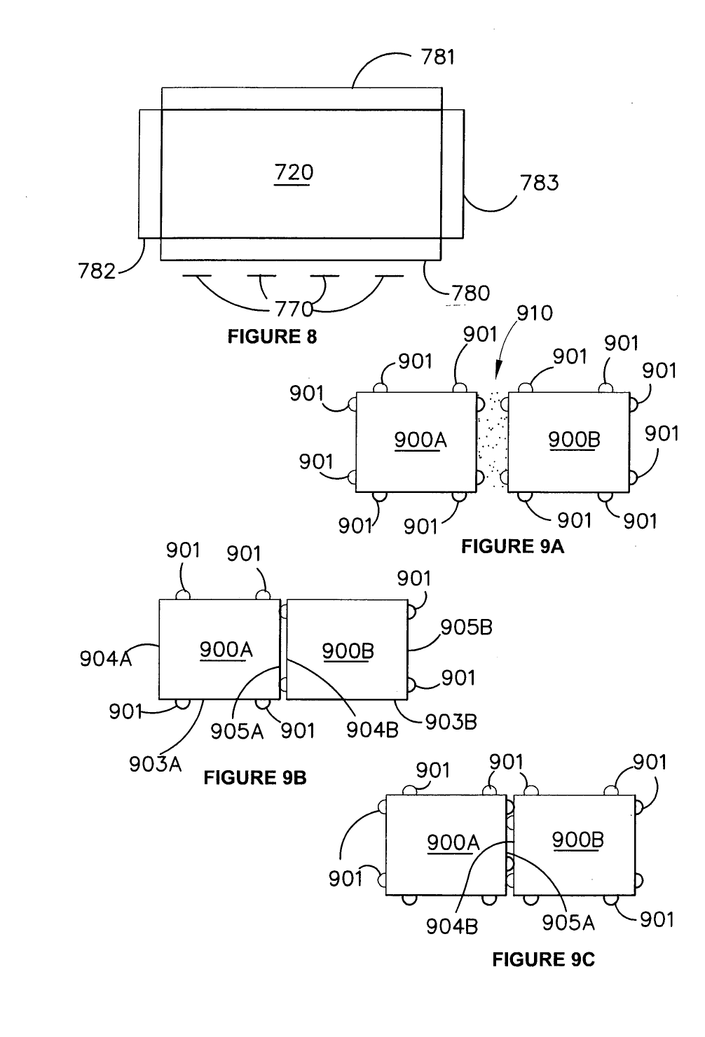

In this embodiment, each edge of each cell is provided with an insulator as described in more detail below in relation to FIG. 8. This is advantageous as it prevents any edge from coming into electrical contact with another electrically conductive element such as the edge of a neighbouring cell, the edge of neighbouring module or a contact such as the interconnect described below.

The insulator is advantageously made from a material which in addition to being electrically insulating is non-wettable to the solder used to solder the photovoltaic device onto the substrate 27. An example of a suitable material is polyimide. Other materials which could be employed for the edge insulators include glass, ceramic, epoxy, and silicone. Depending on the material the insulation material could be applied in a number of different ways, for example spray coating, stamping, ink jet printing, dipping or nozzle dispensing.

The edge insulator does not have to cover the entirety of the edge to be effective and/or does not have to have a uniform thickness provided the coverage is sufficient to effectively prevent any electrical contact with another electrically conductive element. One such example of an edge insulator is shown in FIGS. 9A to 9C, where the edge insulator of each photovoltaic device 900 is provided by two insulator members 901. Persons skilled in the art will appreciate that there could be more than two insulator members acting to protect an edge and that the actual number will depend on factors such as the length of each side and the size of each member. The insulator members can be very small with the size based on the minimum separation required to enable sealant to flow between the cells to insulate them. In an alternative embodiment such as in a lower power application where the cells are not encapsulated in an insulating sealant, the size of the insulator members may be based on the minimum separation required to inhibit breakthrough contact across a gap between the cells for an embodiment.

FIG. 9A shows a general arrangement where each side of each photovoltaic device 900 has an edge insulator formed by two insulator members 901 with insulating sealant 910 disposed between the two photovoltaic devices 900. FIG. 9B show an arrangement where the insulator members 901 are provided on the top edge 902A and bottom edge 903A of a first photovoltaic device and on the left edge 904B and right edge 905B of a second photovoltaic device. FIG. 9C shows that even where the insulator members 901 of respective photovoltaic devices 900 are offset from one another as between the right edge 905A of first photovoltaic device 900A and the left edge 904B of second photovoltaic device 900B, the edges are protected.

Exemplary cell dimensions are 9.95×14.95×0.180 mm and exemplary module dimensions are 60.5×60.5 mm (the cover glass is 60.2×60.2 mm; the ceramic substrate is 60.4×60.4 mm; and there is an allowance of 0.1 mm for silicone encapsulant overspill. Accordingly it will be appreciated that when 24 cells are packed into a module at a separation of about 50 microns, a slight lateral displacement of one cell toward another can significantly narrow the 50 micron gap so that without the edge insulator there is a risk of arcing, noting that as cells are improved voltage may increase for example to 300V. A typical separation between cells of adjoining modules is around 600 microns and the potential between cell is about 315V (but again could increase, for example to 1000V).

### Embodiment Employing Interconnect

FIG. 7 shows a an interconnect in the form of a positive terminal interconnect from the top contact 750 to a positive terminal metal layer 760 of a portion 700 of a triple-junction cell. (Persons skilled in the art will appreciate that the embodiment is equally applicable to N-on-P cells as it is to P-on-N cells.)

The triple-junction cell 700 is shown schematically in FIG. 7. Further details of triple-junction cells, their materials and manufacture, are available from their manufacturers, for example from Spectrolab, Inc of Sylmar, Calif., USA.

Cell 700 has a multi-junction region 710 and a Germanium substrate region 720. A negative terminal metal layer 730 is formed at the base 725 of the substrate region 720 but set back from the outermost corner edge 721 of the substrate. A separator layer 740 is interposed between the negative terminal metal layer 730 and a positive terminal metal layer 760. The separator layer 740 is formed from a material such as silicon dioxide, silicon nitride, silicon oxy-nitride, aluminium oxide or polyimide to insulate the layers 730,760 from one another while allowing heat to be conducted from negative terminal metal layer to the positive terminal metal layer and ultimately to the cooled substrate 27 described above. That is, the separator layer has a heat transfer characteristic (or a small enough thickness) sufficient to enable the photovoltaic device to be deployed in a receiver of a solar concentrator power generation system in that it enable sufficient heat to be conducted to the cooled substrate to maintain an efficient operating temperature of the photovoltaic device.

Interconnect 770 is formed from a material corresponding to the contact and the positive terminal metal layer, for example silver, silver-plated molybdenum, silver coated invar or silver coated kovar. (Invar is an alloy of iron and nickel having a low coefficient of thermal expansion. Kovar is an alloy of iron and nickel to which cobalt is added which also has a low coefficient of thermal expansion.) The use of a common material (silver) for both the positive terminal metal layer and, at least the surface of the interconnect, enables interconnect 770 to be connected by resistance welding or parallel gap welding. The interconnect can also be connected by solder. The interconnect 770 may be coated with an insulating coating in the region near the insulator 780. In addition, interconnect 770 may be employed without the edge insulator 780. In another example, edge insulation could be provided around the interconnect and or the interconnect could be provided between an edge insulator and the edge.

An advantage of this configuration is that an interconnect is made from the top contact 750 which is on the photon source facing surface (e.g. the surface facing the concentrator) to an underneath surface while maintaining thermal conductivity with the separator layer. This also allows the cells to be more closely packed. When used in conjunction with other cells having an edge insulator, there is a further advantage that the introduction of the interconnect will not increase the prospects of a short-circuit.

FIG. 8 is a cross-section through the substrate region 720 of cell 700. It shows that the cell has a plurality of insulators including two side edge insulators 780,781 and two end edge insulators 782,783 (not to scale). From FIG. 8 it will be apparent that interconnect 770 is shown is formed from a plurality of interconnect portions which are provided on a side edge 780 of the cell.

### Insulation Arrangements in a Photovoltaic Module

For convenience of manufacture each edge of each cell has an edge insulator in a rectangular array photovoltaic module. This has the advantage that it does not matter where in the array each cell is positioned and also ensures that the edge of each module is insulated. However, persons skilled in the art will appreciate that other arrangements are possible provided between them each pair of neighbouring edges of neighbouring cells has an edge insulators so that they are collectively insulated from one another. In one example, some cells could have no insulators while others could have four edges insulated. In another example, each cell could have either two or three insulators.

Further, the above embodiment has been described in relation to an embodiment where the cells are arranged in a two-dimensional array. Other arrangements are possible, for example, the cells could be arranged in abutting relationship on a curved substrate, on a multi-surface substrate such as a cube, or in a linear dense array of cells.

Persons skilled in the art will appreciate that the above drawings are schematic in nature and additional features for implementing the embodiment are not shown for clarity of exposition, for example the triple junctions cells may be used on conjunction with bypass diodes for bypassing dead cells as described in more detail in WO 2004/102678.

Further many variations may be made without departing from the scope of the invention. In particular, features of the embodiments described herein may be employed to form further embodiments.

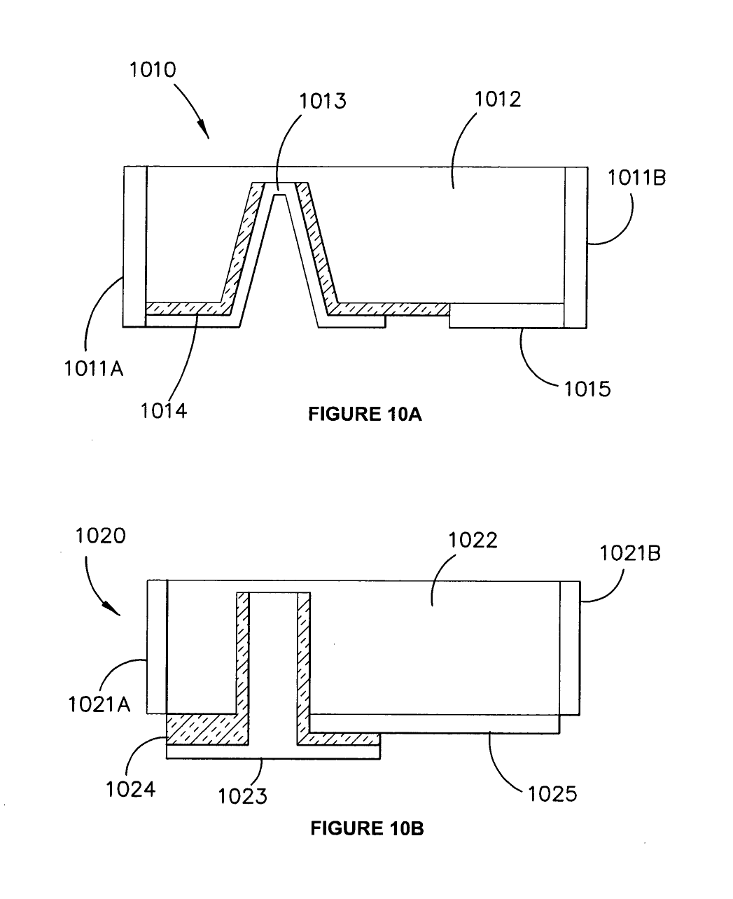

For example, FIG. 10 shows that edge insulation can be used with other forms of interconnects and in particular with a wrap through type interconnect where the contact for the front, photon source facing surface is located on the rear, photon source non-facing surface. One suitable method for fabrication of such a cell is to use epitaxial lift off (ELO) technology, where the cell is fabricated from front to back by depositing layers on a sacrificial substrate.

FIG. 10A shows one exemplary arrangement where a multi-junction photovoltaic cell 1010 has a pair of edge insulators 1011A,1011B provided by a coating of insulating material. The device 1010 has a positive contact 1013 provided by an internal conductive interconnect in the form of layer of metallization which extends through into the emitter region of the cell 1010 from the rear of the cell. The positive contact 1013 is kept separate from the other regions of the multi-junction cell 1010 by an insulation layer 1014. A negative contact 1015 is connected at the rear of the cell.

FIG. 10B shows another exemplary arrangement where a multi-junction photovoltaic cell 1020 has a pair of edge insulators 1021A,1011B provided by a coating of insulating material. The device 1010 has a positive contact member 1023 which extends through into the emitter region of the cell 1020. The positive contact 1023 is kept separate from the other regions of the multi-junction cell 1020 by an insulation layer 1024 surrounding the positive contact member 1023. A negative contact 1025 is connected at the rear of the cell. As no wrap around contacts are required for this type of cell, this type of cell can be very densely packed as no space needs to be left for interconnects to pass beside/between the cells.

In the claims which follow and in the preceding description of the invention, except where the context requires otherwise due to express language or necessary implication, the word “comprise” or variations such as “comprises” or “comprising” is used in an inclusive sense, i.e. to specify the presence of the stated features but not to preclude the presence or addition of further features in various embodiments of the invention.

It is to be understood that, the reference to any prior art publications herein does not constitute an admission that the publication forms a part of the common general knowledge in the art.

1. A photovoltaic device comprising a substantially planar photon source facing side, a plurality of edges extending around the perimeter defined by the photon source facing side, and an edge insulator arranged to prevent at least one edge of the plurality of edges from coming into electrical contact with a neighbouring electrically conductive element when the photovoltaic device is arranged as part of an array of photovoltaic devices.

2. A photovoltaic device as claimed in claim 1, wherein the edge insulator insulates at least the most outwardly extending portion of an outer conductive region of the edge.

3. A photovoltaic device as claimed in claim 1, comprising a plurality of edge insulators corresponding to respective ones of a plurality of edges.

4. A photovoltaic device as claimed in claim 3, wherein the photovoltaic device is rectangular and comprises two to four edge insulators.

5. A photovoltaic device as claimed in claim 3, wherein an edge insulator is provided for each edge.

6. A photovoltaic device as claimed in claim 1, wherein the edge insulator comprises a plurality of insulator members

7. A photovoltaic device as claimed in claim 1, comprising a first contact of a first polarity on the photon source facing side and a conductive interconnect connected between the first contact and a metal layer on a reverse side of the photovoltaic device, the metal layer electrically insulated from a second contact of a second polarity, the interconnect extending around an edge of the photovoltaic device which comprises an edge insulator.

8. A photovoltaic device as claimed in claim 1, wherein the photovoltaic device is a photovoltaic cell.

9. A photovoltaic device as claimed in claim 8, wherein the photovoltaic cell is a multi-junction cell.

10. A photovoltaic device as claimed in claim 9, wherein the multi-junction cell is a triple-junction cell.

11. A photovoltaic device as claimed in claim 1, wherein the photovoltaic device is a monolithically integrated photovoltaic module.

12. A photovoltaic device as claimed in claim 9, wherein the metal layer is a second metal layer and the second contact is formed by a first metal layer connected to a substrate layer of the multi-junction cell.

13. A photovoltaic device as claimed in claim 12, wherein the first and second metal layer are separated by an electrically insulating layer having a heat transfer characteristic sufficient to enable the photovoltaic device to be deployed in a receiver of a solar concentrator power generation system.

14. A photovoltaic device as claimed in claim 12, wherein the electrically insulating layer is formed from a material selected from the group including silicon dioxide, silicon nitride, silicon oxy-nitride, aluminium oxide or polyimide.

15. A photovoltaic device as claimed in claim 1, wherein each edge insulator is formed from a material which is not wettable by solder.

16. A photovoltaic device as claimed in claim 1, comprising an internal electrical interconnect disposed within the cell; a first contact of a first polarity connected to the internal electrical interconnect, and a second contact of a second polarity, the first contact and second contact provided on a reverse side of the photovoltaic device and electrically insulated from one another.

17. A photovoltaic module comprising a plurality of photovoltaic devices, each photovoltaic device comprising a substantially planar photon source facing side, and a plurality of edges extending around the perimeter defined by the photon source facing side, the photovoltaic devices closely packed with neighbouring photovoltaic devices such that there are of pairs of neighbouring edges of neighbouring photovoltaic devices which are at risk of coming into electrical contact with one another, and the photovoltaic devices collectively provided with edge insulators such that there is at least one edge insulator for each pair of edges.

18. A photovoltaic module as claimed in claim 17 and comprising an outer periphery and wherein each edge on the outer periphery comprises an edge insulator.

19. A photovoltaic module as claimed in claim 17, wherein at least one photovoltaic device has no edge insulators.

20. A photovoltaic module as claimed in claim 17, wherein the photovoltaic devices are arranged in a linear array.

21. A photovoltaic module as claimed in claim 17, wherein the photovoltaic devices are arranged in a rectangular array.

22. A photovoltaic module as claimed in claim 17, wherein at least two edges of each photovoltaic device have insulators.

23. A photovoltaic module as claimed in claim 17, wherein each edge of each photovoltaic device has an insulator.

24. A photovoltaic module as claimed in claim 17, wherein each edge insulator is formed from a material which is not wettable by solder.

25. A photovoltaic module as claimed in claim 17, wherein each photovoltaic device comprises a first contact of a first polarity on the photon source facing side and a conductive interconnect connected between the first contact and a metal layer on a reverse side of the photovoltaic device, the metal layer electrically insulated from a second contact of a second polarity, the interconnect extending around an edge of the photovoltaic device which comprises an edge insulator.

26. A photovoltaic module as claimed in claim 17, wherein each photovoltaic device comprises an internal electrical interconnect disposed within the cell; a first contact of a first polarity connected to the internal electrical interconnect, and a second contact of a second polarity, the first contact and second contact provided on a reverse side of the photovoltaic device and electrically insulated from one another.

27. A receiver comprising a plurality of photovoltaic modules as claimed in claim 17.

28. A method of producing electricity comprising concentrating sunlight onto the receiver claimed in claim 27.

29. A photovoltaic device comprising:
a first contact of a first polarity on a photon source facing side;
a second contact on a reverse side of the photovoltaic device, the second contact of a second polarity formed by a first metal layer;
a second metal layer on the reverse side;
at least one separator layer arranged to electrically insulate the first and second metal layers from one another while allowing heat to be conducted from the first metal layer to the second metal layer; and
an electrical interconnect extending from the first contact to the second metal layer.

30. A photovoltaic device as claimed in claim 29, wherein the electrical interconnect extends around an edge of the photovoltaic device which comprises an edge insulator.

31. A photovoltaic device as claimed in claim 29, wherein the separator layer has a heat transfer characteristic sufficient to enable the photovoltaic device to be deployed in a receiver of a solar concentrator power generation system.

32. A photovoltaic device as claimed in claim 31, wherein the electrically insulating layer is formed from a material selected from the group including silicon dioxide, silicon nitride, silicon oxy-nitride, aluminium oxide or polyimide.

33. A photovoltaic device as claimed in claim 29, wherein the electrical interconnect comprises an insulating coating facing at least the edge.

34. A photovoltaic device as claimed in claim 29, wherein the photovoltaic device is a photovoltaic cell.

35. A photovoltaic device as claimed in claim 34, wherein the photovoltaic cell is a multi-junction cell.

36. A photovoltaic device as claimed in claim 35, wherein the multi-junction cell is a triple-junction cell.

37. A photovoltaic device as claimed in claim 29, wherein the photovoltaic device is a monolithically integrated photovoltaic module.

38. A photovoltaic device as claimed in claim 35, wherein the metal layer is a second metal layer and the second contact is formed by a first metal layer connected to a substrate layer of the multi-junction cell.

39. A photovoltaic module comprising a plurality of photovoltaic devices as claimed in claim 29 connected in an electrical circuit.

40. A photovoltaic module as claimed in claim 39, further comprising a substrate on which the photovoltaic devices are mounted, the substrate thermally connected to a cooling circuit.

41. A receiver comprising a plurality of photovoltaic modules as claimed in claim 39.

42. A method of producing electricity comprising concentrating sunlight onto the receiver claimed in claim 41.
